(19) United States
(12) Patent Application Publication
(10) Pub. No.: US 2023/0377854 A1
(43) Pub. Date: Nov. 23, 2023

(54) COOLING PLATE

(71) Applicant: Tokyo Electron Limited, Tokyo (JP)

(72) Inventor: Yoichi YAMADA, Yamanashi (JP)

(21) Appl. No.: 18/313,003

(22) Filed: May 5, 2023

(30) Foreign Application Priority Data
May 19, 2022 (JP) 2022-082118

(51) Int. Cl. H01J 37/32

(52) U.S. Cl. CPC H01J 37/32724; H01J 37/3244; H01J 2237/002; H01J 2237/20235

(57) ABSTRACT

There is provided a cooling plate comprising: lift pins configured to support a substrate; a placing surface capable of having the substrate placed thereon; and a nozzle disposed in the placing surface and configured to blow an inert gas in a combination of a straight flow and a swirling flow toward the substrate lifted from the placing surface by the lift pins.

### CROSS-REFERENCE TO RELATED APPLICATIONS

This application claims priority to Japanese Patent Application No. 2022-082118 filed on May 19, 2022, the entire contents of which are incorporated herein by reference.

### TECHNICAL FIELD

The present disclosure relates to a cooling plate.

### BACKGROUND

Conventionally, in a semiconductor device manufacturing process, substrate processing is performed in which a substrate is processed by rotating the substrate (hereinafter also referred to as wafer), such as a silicon wafer or a compound semiconductor wafer, supplying a processing liquid to a central portion of the rotating substrate, and spreading the processing liquid over the substrate by centrifugal force due to the rotation. In such a case, a temperature difference occurs in the processing liquid between the central portion and an outer peripheral portion of the substrate, which may deteriorate the in-plane uniformity. In this regard, it has been proposed to improve the in-plane uniformity of substrate processing by supplying a gas from a lower surface of the substrate (see Patent Document 1).

### PRIOR ART DOCUMENTS

### Patent Documents

Patent Document 1: Japanese Laid-open Patent Publication No. 2016-63093

### SUMMARY

The present disclosure provides a cooling plate that can cool a substrate faster and more uniformly.

A cooling plate according to one aspect of the present disclosure includes: lift pins configured to support a substrate; a placing surface capable of having the substrate placed thereon; and a nozzle disposed in the placing surface and configured to blow an inert gas in a combination of a straight flow and a swirling flow toward the substrate lifted from the placing surface by the lift pins.

### BRIEF DESCRIPTION OF THE DRAWINGS

The objects and features of the present disclosure will become apparent from the following description of embodiments, given in conjunction with the accompanying drawings, in which:

FIG. 1 is a cross-sectional plan view showing an example of a substrate processing system in one embodiment of the present disclosure;

FIG. 2 is a diagram showing an example of a surface of a cooling plate in this embodiment;

FIGS. 3A and 3B are diagrams showing an example of a cross-section of the cooling plate in this embodiment;

FIGS. 4A and 4B are diagrams showing an example of a straight flow and a swirling flow;

FIGS. 5A and 5B are diagrams showing an example of a nozzle in this embodiment;

FIG. 6 is a diagram showing an example of substrate cooling by a jet flow in this embodiment;

FIG. 7 is a diagram showing an example of a jet flow region near the nozzle in this embodiment; and

FIG. 8 is a flow diagram showing an example of a cooling process in this embodiment.

### DETAILED DESCRIPTION

Embodiments of a cooling plate of the present disclosure will be described in detail below with reference to the accompanying drawings. The following embodiments are not intended to limit the scope of the present disclosure.

Substrate cooling is performed not only in the case of using the above-described processing liquid, but also in various processes. A substrate that has undergone processing that causes the substrate to become hot in a processing chamber, such as plasma processing and annealing processing, remains at a high temperature even after it is unloaded from the processing chamber, so it must be cooled before it is transferred or processed thereafter. For example, to cool the substrate, gas is supplied from a lower surface of the substrate as described above. However, depending on the position of a gas supply nozzle, the faster the substrate is cooled, the more uneven is the temperature in the substrate. Therefore, the substrate may become warped or cracked. Accordingly, it is expected to cool the substrate faster and more uniformly.

### Configuration of Substrate Processing System 1

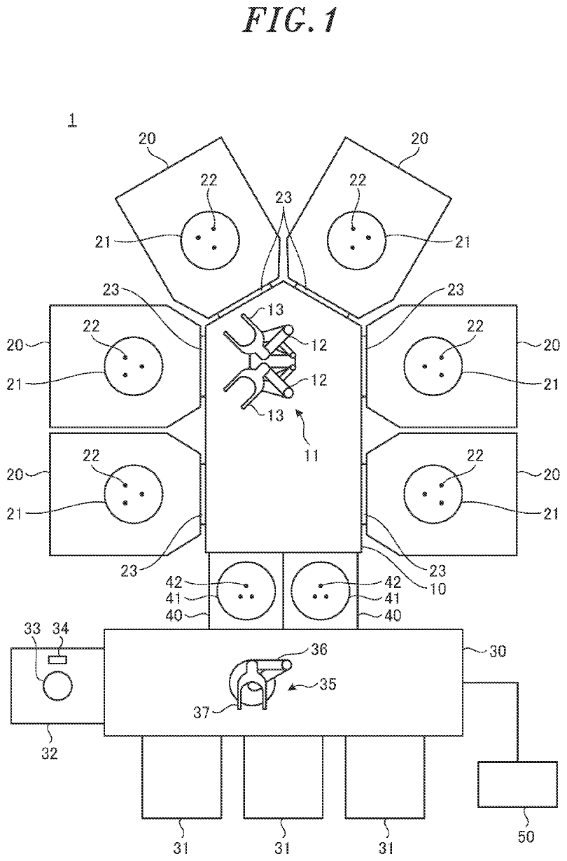

FIG. 1 is a cross-sectional plan view showing an example of a substrate processing system in one embodiment of the present disclosure. A substrate processing system 1 shown in FIG. 1 is a substrate processing system capable of performing various types of processing, such as plasma processing, on a single wafer (e.g., a semiconductor wafer).

As shown in FIG. 1, the substrate processing system 1 includes a transfer module 10, six process modules 20, a loader module 30, and two load lock modules 40.

The transfer module 10 is substantially pentagonal in plan view. The transfer module 10 has a vacuum chamber in which a transfer mechanism 11 is disposed. The transfer mechanism 11 has a guide rail (not shown), two arms 12, and forks 13 disposed at a tip of each arm 12 to support a wafer. Each arm 12 is of the SCARA arm type and is configured to be rotatable and extendable. The transfer mechanism 11 moves along the guide rail and transfers the wafer between the process modules 20 and the load lock modules 40. The transfer mechanism 11 is not limited to the configuration shown in FIG. 1, as long as it can transfer the wafer between the process modules 20 and the load lock modules 40. For example, each arm 12 of the transfer mechanism 11 may be configured to be rotatable and extendable and to move up and down.

The process modules 20 are arranged radially around the transfer module 10 and are connected to the transfer module 10. The process module 20 has a processing chamber and a columnar stage 21 (placing stand) disposed therein. The stage 21 has a plurality of three thin rod-shaped lift pins 22 freely protruding from its upper surface. Each lift pin 22 is arranged on the same circumference in plan view, protrudes from the upper surface of the stage 21 to support and lift the wafer placed on the stage 21, and moves back into the stage 21 to place the supported wafer on the stage 21. After the wafer is placed on the stage 21, the process module 20 decompresses the interior, introduces a processing gas, applies a high-frequency power to the interior to generate a plasma, and performs plasma processing on the wafer with the plasma. The transfer module 10 and the process modules 20 are separated by gate valves 23 that can be opened and closed.

The loader module 30 is disposed facing the transfer module 10. The loader module 30 has a rectangular parallelepiped shape and is an atmospheric transfer chamber maintained in an atmospheric pressure atmosphere. The two load lock modules 40 are connected to one long side of the loader module 30. Three load ports 31 are connected to the other long side of the loader module 30. A FOUP (front-opening unified pod) (not shown), which is a container for accommodating a plurality of wafers, is placed on the load port 31. An aligner 32 is connected to one short side of the loader module 30. A transfer mechanism 35 is disposed in the loader module 30.

The aligner 32 aligns the wafer. The aligner 32 has a rotating stage 33 which is rotated by a drive motor (not shown). The rotating stage 33 has a diameter smaller than that of the wafer, for example, and is configured to be rotatable with the wafer placed on its upper surface. An optical sensor 34 is provided near the rotating stage 33 to detect an outer edge of the wafer. In the aligner 32, the optical sensor 34 detects the center position of the wafer and a direction of a notch with respect to the center of the wafer, and the wafer is transferred to a fork 37, which will be described later, so that the center position of the wafer and the direction of the notch are at a predetermined position and in a predetermined direction. As a result, a transfer position of the wafer is adjusted so that the center position of the wafer and the direction of the notch in the load lock module 40 are at a predetermined position and in a predetermined direction.

The transfer mechanism 35 has a guide rail (not shown), an arm 36, and the fork 37. The arm 36 is of the SCARA arm type, is configured to be movable along the guide rail, and is configured to be rotatable, extendable, and vertically movable. The fork 37 is disposed at the tip of the arm 36 to support the wafer. In the loader module 30, the transfer mechanism 35 transfers the wafer between the FOUP placed on each load port 31, the aligner 32, and the load lock module 40. The transfer mechanism 35 is not limited to the configuration shown in FIG. 1 as long as it can transfer the wafer between the FOUP, the aligner 32, and the load lock module 40.

The load lock modules 40 are disposed between the transfer module 10 and the loader module 30. The load lock module 40 has an internal pressure variable chamber capable of switching between vacuum and atmospheric pressure, and a cylindrical stage 41 disposed therein. When the wafer is loaded from the loader module 30 into the transfer module 10, the load lock module 40 depressurizes the interior and loads the wafer into the transfer module 10 after receiving the wafer from the loader module 30 while maintaining the interior at atmospheric pressure. Further, when the wafer is unloaded from the transfer module 10 to the loader module 30, the ad. lock module 40 pressurizes the interior to atmospheric pressure and loads the wafer into the loader module 30 after receiving the wafer from the transfer module 10 while maintaining the interior vacuum. The stage 41 has a plurality of three thin rod-shaped lift pins 42 freely protruding from its upper surface. Each lift pin 42 is arranged on the same circumference in plan view, supports and lifts the wafer by protruding from the upper surface of the stage 41, and places the supported wafer on the stage 41 by retracting into the stage 41. Further, on the stage 41, the substrate is cooled by blowing an inert gas onto the substrate lifted by each lift pin 42. In other words, the stage 41 is an example of a cooling plate. The load lock modules 40 and the transfer module 10 are separated by gate valves that can be opened. and closed (not shown). Further, the load lock modules 40 and the loader module 30 are separated by gate valves that can be opened and closed (not shown).

The substrate processing system 1 includes a controller 50. The controller 50 is, for example, a computer, and includes a central processing unit (CPU), a random access memory (RAM), a read only memory (ROM), an auxiliary storage device, and the like. The CPU operates based on a program stored in the ROM or the auxiliary storage device, and controls the operation of each component of the substrate processing system 1.

### Cooling Plate

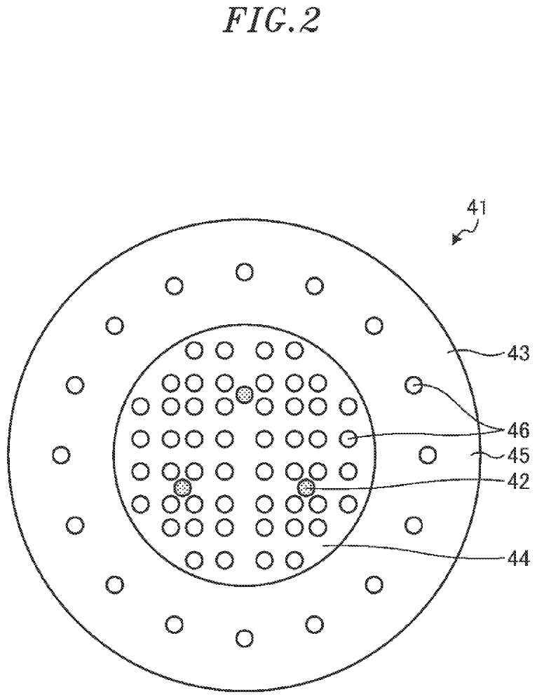

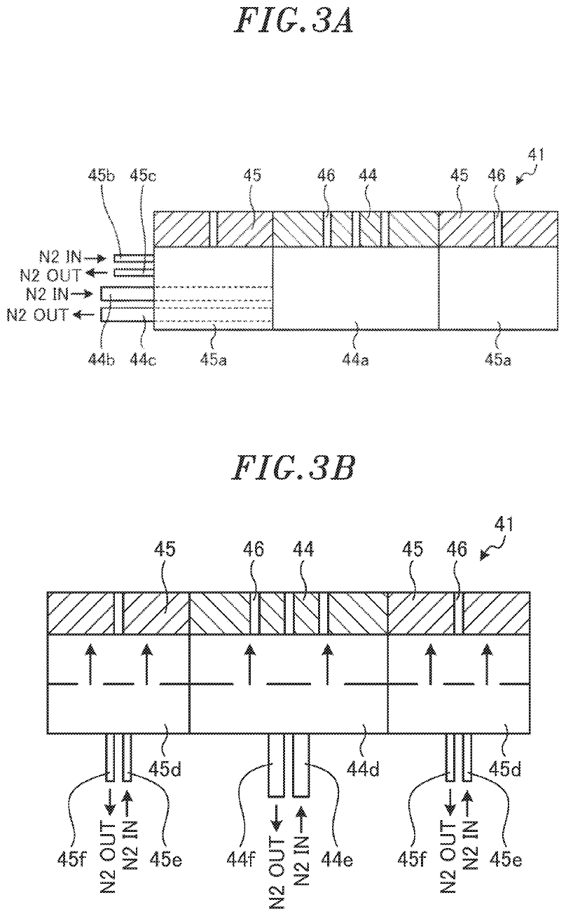

Next, the stage 41, which is the cooling plate, will be described with reference to FIGS. 2, 3A, and 3B. FIG. 2 is a diagram showing an example of a surface of the cooling plate in this embodiment. As shown in FIG. 2, the stage 41 has a circular surface 43 and includes a central portion 44 and an outer peripheral portion 45. Each lift pin 42 and a plurality of nozzles 46 for blowing an inert gas are disposed in the central portion 44. The plurality of nozzles 46 are uniformly arranged on the same circumference, for example, in the outer peripheral portion 45. As the inert gas, for example, nitrogen (N₂) gas or a noble gas such as argon gas can be used.

The nozzles 46 are nozzles for cooling the substrate (wafer) lifted by each lift pin 42 by blowing an inert gas onto the substrate (wafer). Here, the nozzles 46 are hybrid nozzles that blow an inert gas in a combination of a straight flow and a swirling flow. The nozzles 46 are arranged, for example, such that the central portion 44 has a higher density than the outer peripheral portion 45. In other words, the nozzles 46 are arranged such that the outer peripheral portion 45 has a lower density than the central portion 44. Further, as shown in FIG. 2, for example, in the central portion 44, the nozzles 46 are arranged at regular intervals avoiding the lift pins 42. On the other hand, in the outer peripheral portion 45, for example, the nozzles 46 are uniformly arranged on the same circumference. That is, the nozzles 46 are arranged differently between the central portion 44 and the outer peripheral portion 45. Further, the number of nozzles 46 arranged in the central portion 44 is larger than the number of nozzles 46 arranged in the outer peripheral portion 45. The nozzles 46 may be uniformly arranged on a plurality of concentric circles in the outer peripheral portion 45. In this manner, the central portion 44 has a large number and density of nozzles 46 so that the flow rate of the inert gas is high, and the outer peripheral portion 45 has a small number and density of nozzles 46 so that the flow rate of the inert gas is low. Further, in the following description, such zone division into the central portion 44 and the outer peripheral portion 45 and the control of the flow rate of the inert gas ejected from each zone may be referred to as zone jet flow cooling.

FIGS. 3A and 3B are diagrams showing an example of a cross-section of the cooling plate in this embodiment. FIGS. 3A and 3B show a method of supplying an inert gas to the stage 41. FIG. 3A shows a pattern for supplying an inert gas from a side surface of the stage 41, and FIG. 3B shows a pattern for supplying an inert gas from a bottom portion of the stage 41. In FIGS. 3A and 3B, nitrogen gas (N₂) is supplied as the inert gas.

In FIG. 3A, an inert gas is supplied from a pipe 44b to a tank portion 44a provided below the central portion 44. Further, an exhaust pipe 44c is connected to the tank portion 44a, and excess inert gas not ejected from the nozzles 46 is discharged from the pipe 44c. Similarly, an inert gas is supplied from a pipe 45b to a tank portion 45a provided below the outer peripheral portion 45. Further, an exhaust pipe 45c is connected to the tank portion 45a, and excess inert gas not ejected from the nozzles 46 is discharged from the pipe 45c.

In FIG. 3B, an inert gas is supplied from a pipe 44e to a tank portion 44d provided below the central portion 44. Further, an exhaust pipe 44f is connected to the tank portion 44d, and excess inert gas not ejected from the nozzles 46 is discharged from the pipe 44f. Similarly, an inert gas is supplied from a pipe 45e to a tank portion 45d provided below the outer peripheral portion 45. Further, an exhaust pipe 45f is connected to the tank portion 45d, and excess inert gas not ejected from the nozzles 46 is discharged from the pipe 45f. The tank portion 45d may be divided into a plurality of parts in the circumferential direction, for example, and the pipes 45e and 45f may be connected to each tank portion 45d as shown in FIG. 3B. Further, a partition plate is provided in the tank portions 44d and 45d so that the inert gas supplied from the pipes 44e and 45e is not unevenly ejected from the nozzles 46.

### Straight Flow and Swirling Flow

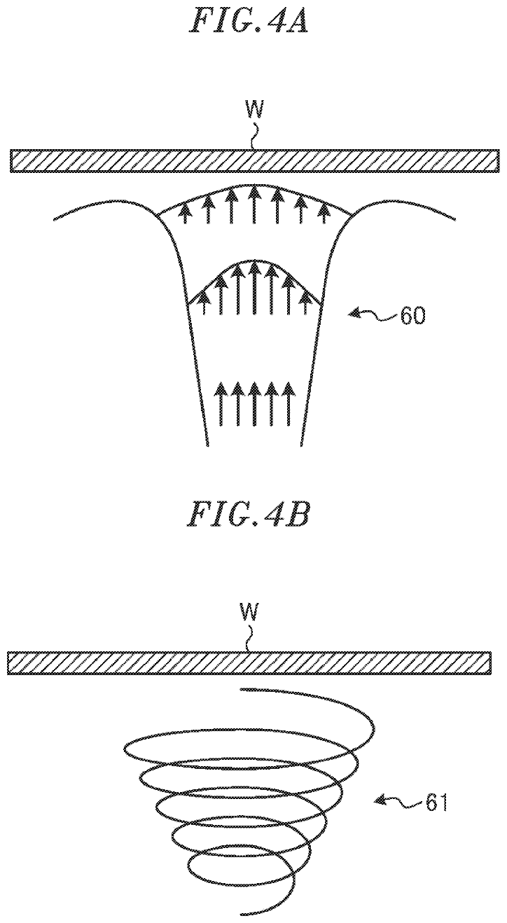

Next, a straight flow and a swirling flow will be described with reference to FIGS. 4A and 4B. FIGS. 4A and 4B are diagrams showing an example of a straight flow and a swirling flow. FIG. 4A shows a straight flow 60 in which the flow of an inert gas is straightened so that the jet flow collides with the substrate W in the vertical direction. FIG. 4B shows a swirling flow 61 in which the flow of an inert gas is swirled so that the jet flow collides with the substrate W obliquely. The straight flow 60 cools a stagnation point region of the impinging jet flow. On the other hand, the swirling flow 61 cools a wall jet flow region where the inert gas flows laterally on the lower surface of the substrate W from the stagnation point. For these reasons, the substrate W can be cooled faster and more uniformly by combining the straight flow 60 and the swirling flow 61.

### Configuration of Nozzle 46

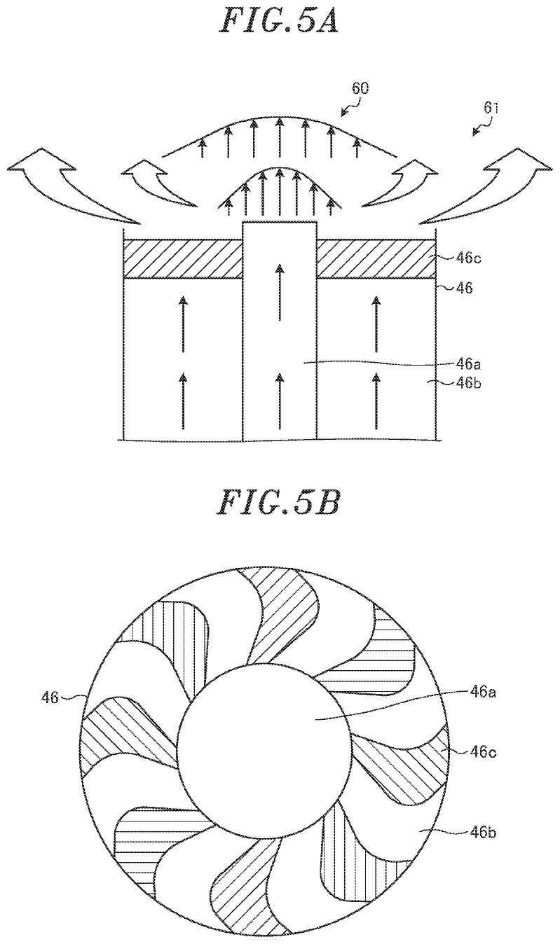

The nozzle 46, which is a hybrid nozzle combining the functions of the straight flow and the swirling flow, is next described with reference to FIGS. 5A and 5B. FIGS. 5A and 5B are diagrams showing an example of the nozzle in this embodiment. FIG. 5A shows a cross-section of the nozzle 46 as viewed from the side. FIG. 5B shows the nozzle 46 as viewed from above. The nozzle 46 has a straight flow nozzle 46a in the central portion and a swirling flow nozzle 46b in the outer peripheral portion surrounding the straight flow nozzle 46a. An ejection port of the swirling flow nozzle 46b is provided with vanes 46c fixed to an inner wall of the swirling flow nozzle 46b, and the inert gas ejected from the ejection port becomes a swirling flow. The straight flow 60 is ejected from an ejection port of the straight flow nozzle 46a. Further, the swirling flow 61 is ejected by the vanes 46c from the ejection port of the swirling flow nozzle 46b. That is, the nozzle 46 has a structure in which the ejection port for the straight flow 60 and the ejection port for the swirling flow 61 are provided in one nozzle 46. The nozzle 46 may eject the swirling flow 61 from a spiral (helical) member (not shown) fixed internally near the ejection port of the swirling flow nozzle 46b instead of the vanes 46c provided at the ejection port of the swirling flow nozzle 46b.

### Region to Which Jet Flow Cooling is Applied

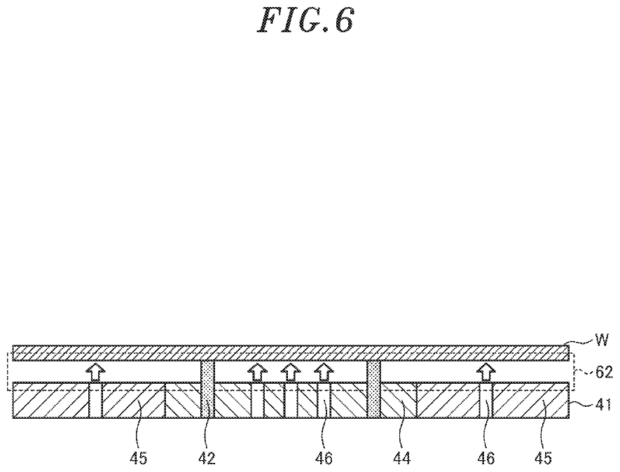

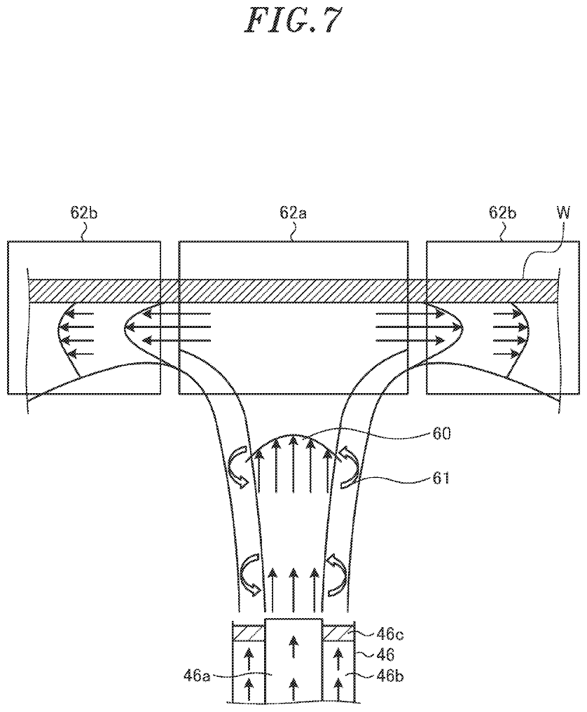

Next, the region to which the jet flow cooling is applied, i.e., the cooling of the substrate by the jet flow, is described with reference to FIGS. 6 and 7. FIG. 6 is a diagram showing an example of substrate cooling by the jet flow in this embodiment. FIG. 7 is a diagram showing an example of a jet flow region near the nozzle in this embodiment. As shown in FIG. 6, the inert gas ejected from each nozzle 46 collides with a back surface of the substrate W in a region 62 between the stage 41 and the substrate W supported by each lift pin 42 on the stage 41. After the collision, the inert gas flows from the central portion 44 of the stage 41 toward the outer peripheral portion 45 side because the internal pressure variable chamber is in a vacuum atmosphere. That is, the region to which the jet flow cooling is applied is the entire back surface of the substrate W. In FIG. 6, some of the nozzles 46 are shown, and other nozzles 46 are omitted.

Here, focusing on one nozzle 46, as shown in FIG. 7, a region 62a where the straight flow 60 ejected from the straight flow nozzle 46a collides with the substrate W becomes a stagnation point region. Further, a region 62b containing an inert gas flowing along the back surface of the substrate W from the region 62a after the straight flow 60 collides with the substrate W and an inert gas flowing along the back surface of the substrate W after the swirling flow 61 ejected from the swirling flow nozzle 46b collides with the substrate W becomes a wall jet flow region. That is, by combining the straight flow and the swirling flow, it is possible to cool not only the region 62a, which is the stagnation point region, but also the region 62b, which is the wall jet flow region.

### Cooling Method

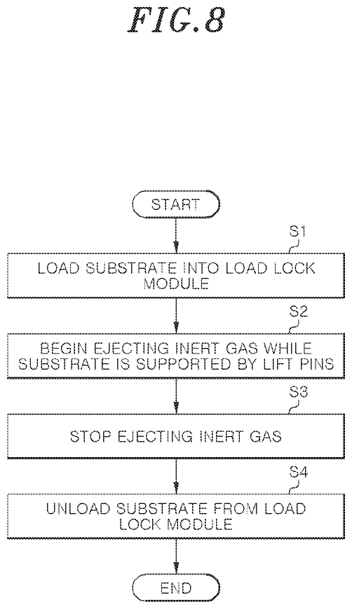

Next, a cooling method according to this embodiment is described. FIG. 8 is a flow chart showing an example of cooling processing in this embodiment.

In the cooling method according to this embodiment, the controller 50 controls the load lock module 40 to open the gate valve (not shown) on the side of the transfer module 10. The controller 50 controls the transfer mechanism 11 to load the substrate W held by the fork 13 into the load lock module 40 (step S1). The controller 50 controls the load lock module 40 to project the lift pins 42 of the stage 41 to receive the substrate W. At this time, the internal pressure variable chamber of the load lock module 40 is in a vacuum atmosphere.

The controller 50 controls the load lock module 40 to close the gate valve (not shown) on the side of the transfer module 10. The controller 50 controls the load lock module 40 to begin ejecting an inert gas while the substrate W is supported by the lift pins 42 (step S2). Here, the substrate W is cooled by the ejection of the inert gas. Further, the controller 50 may control the load lock module 40 to supply a purge gas, such as nitrogen (N₂) gas, as an inert gas into the internal pressure variable chamber of the load lock module 40.

The controller 50 controls the load lock module 40 to stop ejecting the inert gas, for example, after a predetermined time has elapsed (step S3). At this point, it is assumed that the internal pressure variable chamber of the load lock module 40 is in an atmosphere of atmospheric pressure. Further, it is assumed that the cooling of the substrate W has been completed.

The controller 50 controls the load lock module 40 to open the gate valve (not shown) on the side of the loader module 30. The controller 50 controls the transfer mechanism 35 to unload the substrate W supported by the lift pins 42 from the load lock module 40 (step S4). This allows the substrate W to be cooled faster and more uniformly on the stage 41. That is, since the temperature unevenness in the substrate W is suppressed, the substrate W can be prevented from being warped or cracked. Further, since the cooling time can be shortened, the throughput during transfer can be improved. Further, since the substrate W can be uniformly cooled, the transfer accuracy can be improved. Further, the reliability and durability of each device can be improved by reducing the heat load.

In the embodiment described above, the nozzles 46 have the same diameter, but the present disclosure is not limited thereto. For example, the diameter of the nozzles 46 disposed in the central portion 44 and the diameter of the nozzles 46 disposed in the outer peripheral portion 45 may be different. For example, in order to increase the flow rate of the inert gas on the side of the central portion 44, the diameter of the nozzles 46 disposed in the central portion 44 may be larger than the diameter of the nozzles 46 disposed in the outer peripheral portion 45.

As described above, according to this embodiment, the cooling plate (stage 41) includes the lift pins 42 supporting the substrate W, the placing surface (surface 43) on which the substrate W can be placed, and the nozzle 46 that is disposed in the placing surface and blows the inert gas in a combination of the straight flow and the swirling flow onto the substrate W lifted from the placing surface by the lift pins 42. As a result, the substrate W can be cooled faster and more uniformly.

Further, according to this embodiment, the ejection port (swirling flow nozzle 46b) for the swirling flow includes the vanes 46c fixed to its outlet. As a result, the inert gas can be ejected as the swirling flow.

Further, according to this embodiment, the ejection port for the swirling flow has the spiral-shaped portion fixed internally near the outlet. As a result, the inert gas can be ejected as the swirling flow.

Further, according to this embodiment, the plurality of nozzles 46 are disposed in the placing surface. As a result, the substrate W can be cooled faster and more uniformly.

Further, according to this embodiment, the placing surface is circular and includes the central portion 44 and the outer peripheral portion 45, and the nozzles 46 are arranged differently between the central portion 44 and the outer peripheral portion 45. As a result, the flow rate of the inert gas can be different between the central portion 44 and the outer peripheral portion 45.

Further, according to this embodiment, the number of nozzles 46 disposed in the central portion 44 is greater than the number of nozzles 46 disposed in the outer peripheral portion 45. As a result, the central portion 44 can be cooled more.

Further, according to this embodiment, the density of the nozzles 46 disposed in the central portion 44 is higher than the density of the nozzles 46 disposed in the outer peripheral portion 45. As a result, the central portion 44 can be cooled more.

Further, according to this embodiment, the nozzles 46 disposed in the outer peripheral portion 45 are uniformly arranged on the same circumference. As a result, the outer peripheral portion 45 can be uniformly cooled.

Further, according to this embodiment, the diameter of the nozzles 46 disposed in the central portion 44 and the diameter of the nozzles 46 disposed in the outer peripheral portion 45 are different. As a result, the flow rate of the inert gas can be different between the central portion 44 and the outer peripheral portion 45.

Further, according to this embodiment, the diameter of the nozzles 46 disposed in the central portion 44 is larger than the diameter of the nozzles 46 disposed in the outer peripheral portion 45. As a result, the central portion 44 can be cooled more.

Further, according to this embodiment, the inert gas is nitrogen gas. As a result, since the nitrogen gas is inert and has a high thermal conductivity, the substrate W can be cooled without affecting a film or the like formed on the substrate W.

The embodiments disclosed herein should be considered in all respects as illustrative and not restrictive. The embodiments described above may be omitted, substituted, or modified in various ways without departing from the scope and spirit of the appended claims.

Further, in the above-described embodiment, the case in which the central portion 44 and the outer peripheral portion 45 are uniformly cooled has been described, but the present disclosure is not limited thereto. For example, in processing in which the central portion 44 and the outer peripheral portion 45 have different temperatures, the substrate W may be cooled so that the temperature of the entire substrate W becomes uniform after cooling, or so that the central portion 44 and the outer peripheral portion 45 have different temperatures after cooling. Thereby, the flexibility of the processing can be improved.

Further, in the above described embodiment, the substrate W is cooled on the stage 41 of the load lock module 40, but the present disclosure is not limited thereto. For 10 example, the substrate W may be cooled on the stage 21 of the process module 20 or on a stage of a path (not shown).

The present disclosure can also take the following configurations.

(1)

A cooling plate comprising:

lift pins configured to support a substrate;

a placing surface capable of having the substrate placed thereon; and

a nozzle disposed in the placing surface and configured to blow an inert gas in a combination of a straight flow and a swirling flow toward the substrate lifted from the placing surface by the lift pins.

(2)

The cooling plate of (1), wherein the nozzles are provided with an ejection port for the straight flow and an ejection port for the swirling flow in one nozzle.

(3)

The cooling plate of (2), wherein the ejection port for the swirling flow is provided with vanes fixed to its outlet.

(4)

The cooling plate of (2), wherein the ejection port for the swirling flow is provided with a spiral-shaped portion fixed internally near its outlet.

(5)

The cooling plate of (1), wherein a plurality of the nozzles are disposed in the placing surface.

(6)

The cooling plate of (5), wherein the placing surface is circular and includes a central portion and an outer peripheral portion, and

the nozzles are arranged differently between the central portion and the outer peripheral portion.

(7)

The cooling plate of (6), wherein the number of nozzles disposed in the central portion is greater than the number of nozzles disposed in the outer peripheral portion.

(8)

The cooling plate of (6), wherein a density of the nozzles disposed in the central portion is higher than a density of the nozzles disposed in the outer peripheral portion.

(9)

The cooling plate of (6), wherein the nozzles disposed in the outer peripheral portion are uniformly arranged on the same circumference.

(10)

The cooling plate of (6), wherein a diameter of the nozzles disposed in the central portion and a diameter of the nozzles disposed in the outer peripheral portion are different.

(11)

The cooling plate of (10), wherein the diameter of the nozzles disposed in the central portion is larger than the diameter of the nozzles disposed in the outer peripheral portion.

(12)

The cooling plate of (1), wherein the inert gas is nitrogen gas.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A cooling plate comprising:
lift pins configured to support a substrate;
a placing surface capable of having the substrate placed thereon; and
a nozzle disposed in the placing surface and configured to blow an inert gas in a combination of a straight flow and a swirling flow toward the substrate lifted from the placing surface by the lift pins.

2. The cooling plate of claim 1, wherein the nozzle is provided with an ejection port for the straight flow and an ejection port for the swirling flow in one nozzle.

3. The cooling plate of claim 2, wherein the ejection port for the swirling flow is provided with vanes fixed to its outlet.

4. The cooling plate of claim 2, wherein the ejection port for the swirling flow is provided with a spiral-shaped portion fixed internally near its outlet.

5. The cooling plate of claim 1, wherein a plurality of the nozzles are disposed in the placing surface.

6. The cooling plate of claim 5, wherein the placing surface is circular and includes a central portion and an outer peripheral portion, and
the nozzles are arranged differently between the central portion and the outer peripheral portion.

7. The cooling plate of claim 6, wherein the number of nozzles disposed in the central portion is greater than the number of nozzles disposed in the outer peripheral portion.

8. The cooling plate of claim 6, wherein a density of the nozzles disposed in the central portion is higher than a density of the nozzles disposed in the outer peripheral portion.

9. The cooling plate of claim 6, wherein the nozzles disposed in the outer peripheral portion are uniformly arranged on the same circumference.

10. The cooling plate of claim 6, wherein a diameter of the nozzles disposed in the central portion and a diameter of the nozzles disposed in the outer peripheral portion are different.

11. The cooling plate of claim 10, wherein the diameter of the nozzles disposed in the central portion is larger than the diameter of the nozzles disposed in the outer peripheral portion.

12. The cooling plate of claim 1, wherein the inert gas is nitrogen gas.
